(19) United States
(12) Patent Application Publication
(10) Pub. No.: US 2021/0018905 A1
(43) Pub. Date: Jan. 21, 2021

(54) STATE MANAGEMENT SYSTEM AND STATE MANAGEMENT METHOD

(71) Applicant: Tokyo Electron Limited, Tokyo (JP)

(72) Inventors: Ryota AOI, Hokkaido (JP); Yasuhiko OKADA, Iwate (JP); Yoshitaka ENOKI, Iwate (JP); Kakeru HIRATOKO, Iwate (JP)

(21) Appl. No.: 16/926,944

(22) Filed: Jul. 13, 2020

(30) Foreign Application Priority Data
Jul. 17, 2019 (JP) 2019-132259

(51) Int. Cl. G05B 23/02

(52) U.S. Cl. CPC G05B 23/0259; G05B 23/0272

(57) ABSTRACT

A state management system includes: an acquisition unit that acquires data accumulated in an apparatus; an execution unit that executes a process of combining a plurality of types of data selected in advance among the acquired data and calculating one index indicating a normality of the apparatus at predetermined intervals; and a display controller that displays the calculated one index in a display.

### CROSS-REFERENCE TO RELATED APPLICATION

This application is based on and claims priority from Japanese Patent Application No. 2019-132259 filed on Jul. 17, 2019 with the Japan Patent Office, the disclosure of which is incorporated herein in its entirety by reference.

### TECHNICAL FIELD

The present disclosure relates to a state management system and a state management method.

### BACKGROUND

In various apparatuses such as a substrate processing apparatus, the data is generally monitored during operation, and when an abnormality is detected, an operator is notified of the abnormality. Further, the operator who has received the notification stops the operation of the apparatus as necessary and performs a maintenance on the apparatus.

Meanwhile, in order to reduce the number of scenes in which the operating apparatus is stopped and improve the productivity of the apparatus, it is effective, for example, for an operator to grasp the state of the operating apparatus and take appropriate measures before an abnormality is detected thereby preventing the occurrence of an abnormality.

However, since there is a wide variety of data managed by the apparatus, it is not an easy task for an operator to monitor all the data before the abnormality is detected and grasp the state of the apparatus. See, for example, Japanese Patent Laid-Open Publication No. 2017-183708.

### SUMMARY

According to an aspect of the present disclosure, a state management system includes: an acquisition unit that acquires data accumulated in an apparatus; an execution unit that executes a process of combining a plurality of types of data selected in advance among the acquired data and calculating one index indicating a normality of the apparatus at predetermined intervals; and a display controller that displays the calculated one index.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating a system configuration of a state management system and an example of data accumulated in a substrate processing apparatus.

FIG. 2 is a diagram illustrating an example of a hardware configuration of an analysis apparatus.

FIG. 3 is a diagram illustrating an example of a functional configuration of the analysis apparatus.

FIG. 4 is a diagram illustrating a specific example of a health value calculation process by the analysis apparatus.

FIG. 5 is a flowchart illustrating a flow of the health value calculation process by the analysis apparatus.

FIG. 6 is a diagram illustrating a specific example of an operation rate calculation process by the analysis apparatus.

FIG. 7 is a flowchart illustrating a flow of the operation rate calculation process by the analysis apparatus.

FIG. 8 is a diagram illustrating examples of a management screen and a detailed screen displayed on the analysis apparatus.

FIG. 9 is a diagram illustrating specific examples of health values and operation rates calculated for a plurality of substrate processing apparatuses.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, the present embodiment will be described with reference to the accompanying drawings. Also, in the present specification and drawings, components having substantially the same functional configurations will be denoted by the same symbols, and the descriptions thereof will be omitted.

### First Embodiment

<System Configuration of Status Management System and Example of Data Accumulated in Substrate Processing Apparatus>

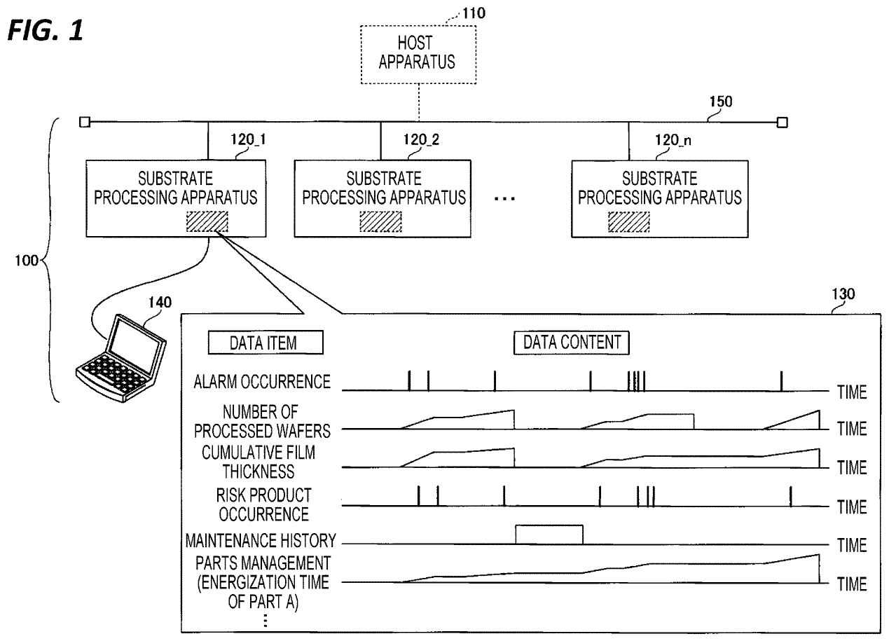

First, descriptions will be made on the system configuration of a state management system according to a first embodiment and an example of data accumulated in each substrate processing apparatus constituting the state management system. FIG. 1 is a diagram illustrating the system configuration of the state management system and an example of data accumulated in a substrate processing apparatus.

As illustrated in FIG. 1, the state management system 100 includes substrate processing apparatuses 120_1 to 120_n and an analysis apparatus 140. The substrate processing apparatuses 120_1 to 120_n and the analysis apparatus 140 are connected by wire or wirelessly.

The substrate processing apparatuses 120_1 to 120_n are connected to a host apparatus 110 via a network 150 and execute a semiconductor manufacturing process based on an instruction from the host apparatus 110. Further, it is assumed that the substrate processing apparatuses 120_1 to 120_n have accumulated therein a wide variety of data managed by the substrate processing apparatuses 120_1 to 120_n.

In FIG. 1, the accumulated data 130 represents an example of data managed by the substrate processing apparatus 120_1. As illustrated in FIG. 1, the accumulated data 130 includes data items and data contents.

In the example of FIG. 1, “alarm occurrence,” “number of processed wafers,” “cumulative film thickness,” “risk product occurrence,” “maintenance history,” and “parts management (energization time of parts A)” are included as the data items. Further, it is not necessary to say that the data items included in the accumulated data 130 are not limited to those described above.

By being connected to the substrate processing apparatuses 120_1 to 120_n, the analysis apparatus 140 continuously acquires the accumulated data accumulated in the substrate processing apparatuses 120_1 to 120_n. The example of FIG. 1 represents a state in which the analysis apparatus 140 is connected to the substrate processing apparatus 120_1. Hereinafter, in the present embodiment, descriptions will be made on details when the analysis apparatus 140 is connected to the substrate processing apparatus 120_1.

When connected to the substrate processing apparatus 120_1, the analysis apparatus 140 continuously acquires the accumulated data 130 from the substrate processing apparatus 120_1, calculates an index indicating the state of the substrate processing apparatus 120_1 at predetermined intervals based on the acquired accumulated data 130, and displays the index to an operator. Specifically, the analysis apparatus 140 calculates a “health value” and an “operation rate” of the substrate processing apparatus 120_1 as indexes indicating the state of the substrate processing apparatus 120_1, and displays such information to the operator.

The “health value” is one index (first index) indicating the normality of the substrate processing apparatus 120_1. The analysis apparatus 140 calculates the health value by combining data contents of a pre-specified target section as data contents corresponding to a plurality of pre-selected data items (e.g., data items related to the occurrence of an abnormality) in the acquired accumulated data 130.

In this way, in the analysis apparatus 140, one index is calculated by combining the data contents corresponding to a plurality of types of data items in the accumulated data 130, and displayed to the operator. As a result, the monitoring load on the operator may be reduced as compared with a case where the operator monitors all the various accumulated data accumulated in the substrate processing apparatus 120_1. Further, the analysis apparatus 140 calculates the health value of the substrate processing apparatus 120_1 as one index and displays the value to the operator. Thus, the operator may directly grasp the current state of the substrate processing apparatus 120_1.

Meanwhile, the “operation rate” is one index (second index) indicating the ratio at which the substrate processing apparatus 120_1 is in an operable state. The analysis apparatus 140 calculates the operation rate by extracting the data content of the target section specified in advance from the accumulated data 130 acquired from the substrate processing apparatus 120_1, as the data content corresponding to the data item indicating whether the substrate processing apparatus 120_1 is in an operable state.

In this way, in the analysis apparatus 140, one index is calculated using the data content corresponding to the data item indicating whether the substrate processing apparatus 120_1 is in the operable state, and displayed to the operator. As a result, the monitoring load on the operator may be reduced as compared with the case where the operator monitors all the various accumulated data accumulated in the substrate processing apparatus 120_1. Further, the analysis apparatus 140 calculates the operation rate of the substrate processing apparatus 120_1 as one index, and displays the operation rate to the operator. Thus, the operator may directly grasp the past (latest) state of the substrate processing apparatus 120_1.

In addition, the operator monitors the health value and the operation rate displayed on the analysis apparatus 140, and when these values are lowered (before an abnormality is detected), the operator takes measures according to the cause of the drop. This allows the operator to prevent the occurrence of an abnormality in the substrate processing apparatus 120_1.

<Hardware Configuration of Analysis Apparatus>

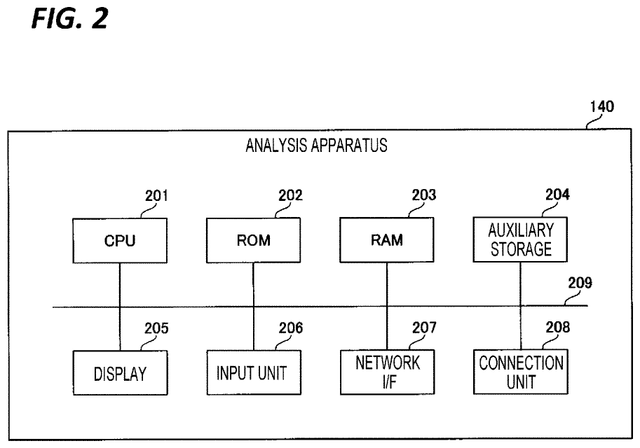

Next, the hardware configuration of the analysis apparatus 140 will be described. FIG. 2 is a diagram illustrating an example of the hardware configuration of the analysis apparatus. As illustrated in FIG. 2, the analysis apparatus 140 includes a central processing unit (CPU) 201, a read only memory (ROM) 202, and a random access memory (RAM) 203. The CPU 201, the ROM 202, and the RAM 203 form a so-called computer.

Further, the analysis apparatus 140 also includes an auxiliary storage 204, a display 205, an input unit 206, a network interface (I/F) 207, and a connection unit 208. The respective pieces of hardware of the analysis apparatus 140 are connected to each other via a bus 209.

The CPU 201 is a device that executes various programs (e.g., an analysis program to be described later) installed in the auxiliary storage 204. The ROM 202 is a non-volatile memory. The ROM 202 functions as a main storage device that stores various programs and data necessary for the CPU 201 to execute various programs installed in the auxiliary storage 204. Specifically, the ROM 202 stores a boot program such as a basic input/output system (BIOS) and an extensible firmware interface (EFI).

The RAM 203 is a volatile memory such as a dynamic random access memory (DRAM) or a static random access memory (SRAM). The RAM 203 functions as a main storage device that provides a work area that is expanded when the various programs installed in the auxiliary storage 204 are executed by the CPU 201.

The auxiliary storage 204 is an auxiliary storage device that stores various programs and information used when the various programs are executed. A data storage described later is implemented in the auxiliary storage 204.

The display 205 is a display device that displays various screens (e.g., a customization screen, a management screen, and a detailed screen to be described later). The input unit 206 is an input device for an operator to input various instructions to the analysis apparatus 140.

The network OF 207 is a communication device that is connected to an external network (not illustrated). The connection unit 208 is a connection device connected to the substrate processing apparatus 120_1.

<Functional Configuration of Analysis Apparatus>

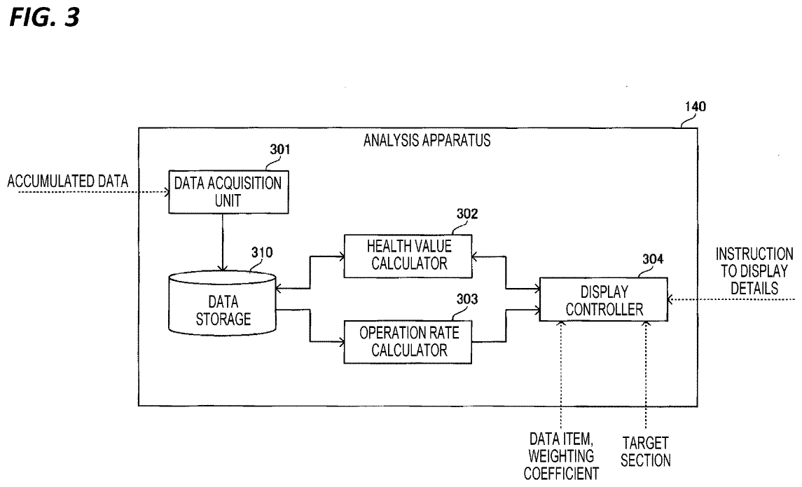

Next, the functional configuration of the analysis apparatus 140 will be described. FIG. 3 is a diagram illustrating an example of a functional configuration of the analysis apparatus. As described above, the analysis program is installed in the analysis apparatus 140, and by executing the analysis program, the analysis apparatus 140 functions as a data acquisition unit 301, a health value calculator 302, an operation rate calculator 303, and a display controller 304.

The data acquisition unit 301 continuously acquires the accumulated data 130 accumulated by the substrate processing apparatus 120_1 by connecting the analysis apparatus 140 to the substrate processing apparatus 120_1, and stores the accumulated data 130 in the data storage 310.

The health value calculator 302 is an example of a first execution unit. The health value calculator 302 reads, from the accumulated data stored in the data storage 310, the data content of the pre-specified target section as the data content corresponding to the pre-selected data item based on an instruction from the display controller 304. Further, the health value calculator 302 calculates a “deduction value” of each data item by multiplying the read data content by a weighting coefficient specified in advance.

In addition, the health value calculator 302 calculates the health value by subtracting the deduction value of each data item from the full score value (e.g., 100). The health value calculator 302 also notifies the display controller 304 of the calculated health value.

The operation rate calculator 303 is an example of a second execution unit. The operation rate calculator 303 reads, from the accumulated data stored in the data storage 310, the data content of the pre-specified target section as the data content corresponding to a data item indicating whether the substrate processing apparatus is in the operable state based on an instruction from the display controller 304.

In addition, the operation rate calculator 303 calculates the time length during which the substrate processing apparatus is in an operable state based on the read data content. Further, the operation rate calculator 303 calculates the ratio of the calculated time length occupying the pre-specified target section as the operation rate, and notifies the display controller 304 of the ratio.

The display controller 304 receives a selection or designation of data items and weighting coefficients used for calculating the health value, and notifies the health value calculator 302 of the selection or designation. Further, the display controller 304 receives the designation of the target section used for calculating the health value and the operation rate, and notifies the health value calculator 302 and the operation rate calculator 303 of the designation.

In addition, the display controller 304 instructs the health value calculator 302 and the operation rate calculator 303 to calculate the health value and the operation rate at predetermined intervals. In response to the instruction for the calculation, the display controller 304 also displays the health value and the operation rate notified from the health value calculator 302 and the operation rate calculator 303 on the management screen.

In addition, the display controller 304 displays the health value and the operation rate that were notified by the health value calculator 302 and the operation rate calculator 303 in the past on the management screen. Thus, the operator may grasp the transition of the health value and the operation rate up to the present.

Further, in response to displaying the health value on the management screen, when an instruction for detailed display is input from the operator, the display controller 304 instructs the health value calculator 302 to notify the data content corresponding to the data item for which the deduction value is calculated. Further, in the display controller 304, when the health value calculator 302 notifies the data content corresponding to the data item for which the deduction value is calculated, the data content is displayed on the detailed screen.

<Specific Example of Health Value Calculation Process>

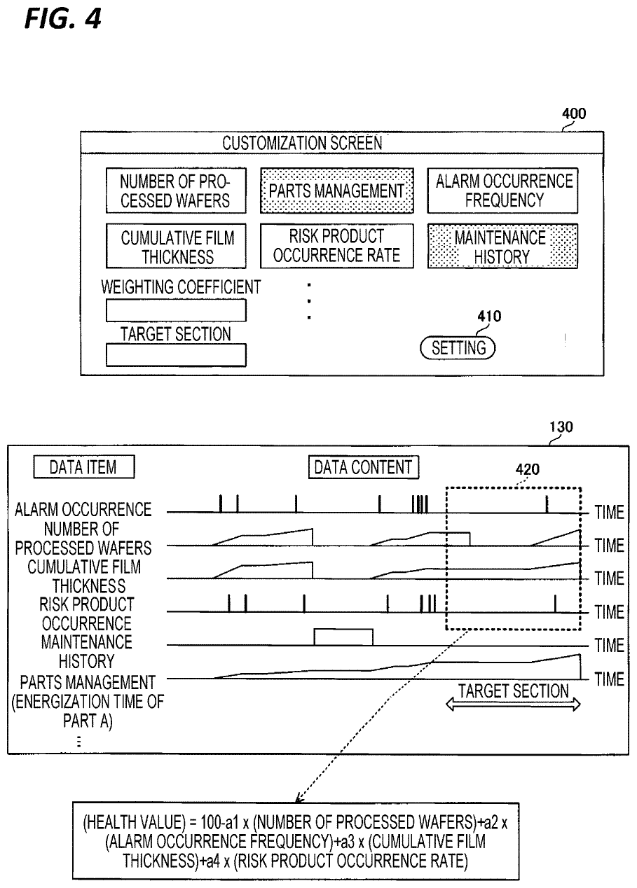

Next, descriptions will be made on a specific example of a health value calculation process by the analysis apparatus 140. FIG. 4 is a diagram illustrating a specific example of the health value calculation process. As illustrated in FIG. 4, when the analysis apparatus 140 performs the health value calculation process, the display controller 304 first displays a customization screen 400 on the display 205 and receives the selection of the data item used to calculate the health value.

As illustrated in FIG. 4, the customization screen 400 displays a list of data items that are included in the accumulated data 130 accumulated in the substrate processing apparatus 120_1. The operator selects a data item used to calculate a health value from the data items listed on the customization screen 400. In the example of the customization screen 400 in FIG. 4, among the data items displayed in the list, the “number of processed wafers,” the “alarm occurrence frequency,” the “cumulative film thickness,” and the “risk product occurrence rate” are selected as the data items used to calculate the health value.

In addition, as illustrated in FIG. 4, the customization screen 400 further includes a weighting coefficient designation field that designates a weighting coefficient used for calculating a health value. Every time the operator selects a data item, the operator may input a weighting coefficient in the weighting coefficient designation field and press a setting button 410 to designate the weighting coefficient of each data item.

In addition, as illustrated in FIG. 4, the customization screen 400 further includes a target section designation field that designates a target section used for calculating a health value. The operator may specify a target section used for calculating the health value by inputting the target section in the target section designation field and pressing the setting button 410.

In the case of the example in FIG. 4, the health value calculator 302 calculates the health value based on the following equation using the data content of the target section surrounded by a dotted line 420 in the accumulated data 130.

(Health value)=100−a1×(number of processed wafers)−a2×(alarm occurrence frequency)−a3×(cumulative film thickness)−a4×(risk product occurrence rate) (Equation 1)

Further, the symbols “a1” to “a4” represent weighting coefficients specified for each selected data item. Also, “100” is a full score value, and “a1×(number of processed wafers)” represents a deduction value of a data item=“number of processed wafers.” Similarly, “a2×(alarm occurrence frequency)” represents a deduction value of a data item=“alarm occurrence frequency,” “a3×(cumulative film thickness)” represents a deduction value of a data item=“cumulative film thickness,” and “a4×(risk product occurrence rate)” represents a deduction value of a data item=“RISK product occurrence rate.” However, in calculating the deduction value, the health value calculator 302 performs, for example, a normalization process on the data content corresponding to the selected data item.

<Flow of Health Value Calculation Process>

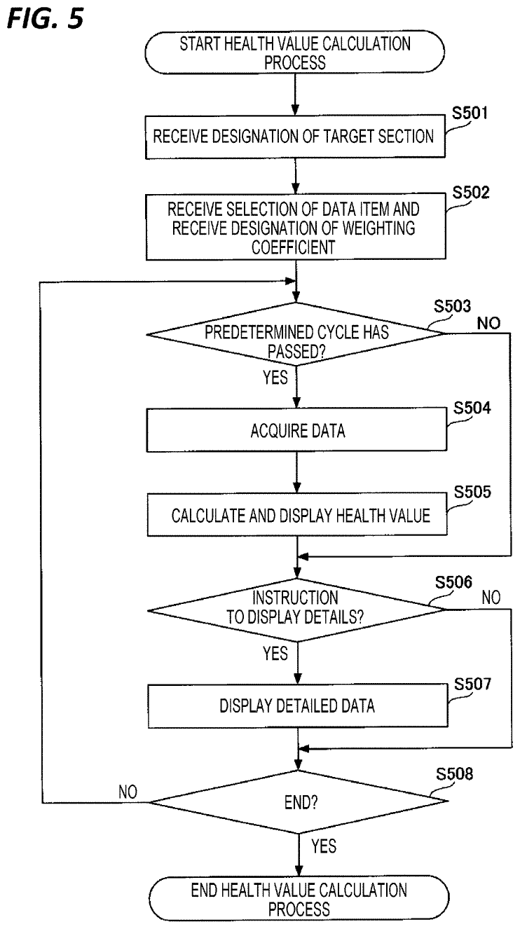

Next, descriptions will be made on a flow of the health value calculation process by the analysis apparatus 140. FIG. 5 is a flowchart illustrating a flow of the health value calculation process by the analysis apparatus. Further, during execution of the health value calculation process, the data acquisition unit 301 continuously acquires the accumulated data 130 from the substrate processing apparatus 120_1 and stores the accumulated data 130 in the data storage 310.

In step S501, the display controller 304 displays the customization screen 400 and receives the designation of the target section. Further, the display controller 304 notifies the health value calculator 302 of the received target section.

In step S502, the display controller 304 receives the selection of the data item on the customization screen 400 and receives the designation of the weighting coefficient for the data item for which the selection is received. Further, the display controller 304 notifies the health value calculator 302 of the received target section and weighting coefficient.

In step S503, the display controller 304 determines whether a predetermined cycle has passed. When it is determined in step S503 that the predetermined cycle has not passed (in the case of “No” in step S503), the process proceeds to step S506.

When it is determined in step S503 that the predetermined cycle has passed (in the case of “Yes” in step S503), the process proceeds to step S504. In step S504, the display controller 304 instructs the health value calculator 302 to calculate a health value. Further, the health value calculator 302 reads, from the data storage 310, the data content of the notified target section as the data content corresponding to the data item notified by the display controller 304.

In step S505, the health value calculator 302 calculates the deduction value of each selected data item by multiplying the read data content by the weighting coefficient notified by the display controller 304. Further, the health value calculator 302 calculates the health value by subtracting the calculated deduction value from the full score value. Further, the display controller 304 displays the health value calculated by the health value calculator 302 on the management screen and displays the health values calculated in the past on the management screen.

In step S506, the display controller 304 determines whether an instruction to display details of the health value has been received. When it is determined in step S506 that the instruction to display details has not been received (in the case of “No” in step S506), the process proceeds to step S508.

Meanwhile, when it is determined in step S506 that the instruction to display details has been received (in the case of “Yes” in step S506), the process proceeds to step S507. In step S507, the display controller 304 instructs the health value calculator 302 to notify the data content corresponding to the data item for which the deduction value has been calculated. In addition, the display controller 304 displays the data content corresponding to the data item for which the deduction value is calculated, which is notified from the health value calculator 302 according to the instruction, on the detailed screen.

In step S508, the display controller 304 determines whether to end the health value calculation process. When it is determined in step S508 that the health value calculation process is to be continued (in the case of “No” in step S508), the process returns to step S503. When it is determined in step S508 that the health value calculation process is to be ended (in the case of “Yes” in step S508), the health value calculation process is ended.

In this way, the analysis apparatus 140 calculates the health value as an index indicating the current state of the substrate processing apparatus 120_1 at predetermined intervals. Thus, the operator may monitor the health value and, when the health value is lowered (before the abnormality is detected), may take measures according to the cause of the drop. This allows the operator to prevent the occurrence of an abnormality in the substrate processing apparatus 120_1.

<Specific Example of Operation Rate Calculation Process>

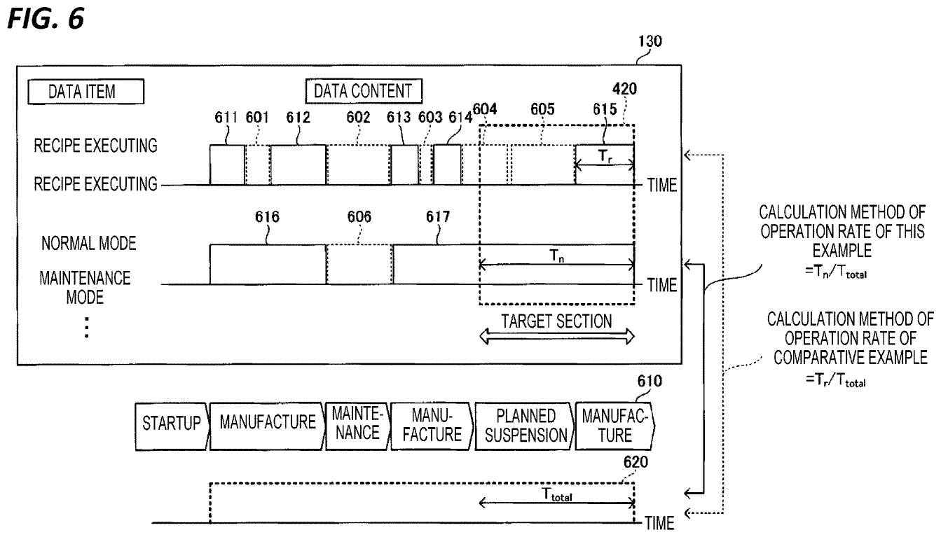

Next, descriptions will be made on a specific example of an operation rate calculation process by the analysis apparatus 140. FIG. 6 is a diagram illustrating a specific example of the operation rate calculation process. The operation rate calculator 303 of the analysis apparatus 140 calculates the operation rate for the target section specified in the customization screen 400 (see, e.g., FIG. 4) (target section surrounded by the dotted line 420).

In FIG. 6, the accumulated data 130 is an example of data managed by the substrate processing apparatus 120_1, and here indicates data particularly relating to the operation of the substrate processing apparatus 120_1. As illustrated in FIG. 6, the data related to the operation of the substrate processing apparatus 120_1 includes, for example, “recipe executing/recipe not executing” and “normal mode/maintenance mode” as data items.

Among the data, the data content indicating whether the substrate processing apparatus 120_1 actually processes a substrate based on the recipe (whether the substrate processing apparatus 120_1 is in operation) is associated with “recipe executing/recipe not executing.” In FIG. 6, solid lines 611 to 615 indicate that the substrate processing apparatus 120_1 actually processes the substrate based on the recipe (in operation). In FIG. 6, the solid lines 601 to 605 indicate that the substrate processing apparatus 120_1 is not processing the substrate (not in operation). In the case of the example in FIG. 6, in the target section surrounded by the dotted line 420, the time length during which the substrate processing apparatus 120_1 actually processes the substrate based on the recipe (the operating time length) becomes “Tr.”

Among the dotted lines 601 to 605, dotted lines 601, 603, and 604 respectively indicate a state in which the substrate processing apparatus 120_1 has completed processing the target number of substrates in the manufacturing process and there is no substrate to be processed immediately (standby state). Further, the dotted line 602 indicates a state where the substrate is not processed due to maintenance on the substrate processing apparatus 120_1. Also, the dotted line 605 indicates a state where the substrate is not processed due to a planned suspension period of the substrate processing apparatus 120_1.

Meanwhile, the “normal mode/maintenance mode” is associated with the data content indicating whether the substrate processing apparatus 120_1 may actually process a substrate (whether the substrate processing apparatus 120_1 is in an operable state). In FIG. 6, solid lines 616 to 617 indicate the normal mode, which indicates that the substrate processing apparatus 120_1 is in a state in which the substrate processing apparatus 120_1 may actually process the substrate (in an operable state). In FIG. 6, the dotted line 606 indicates the maintenance mode, which indicates that the substrate processing apparatus 120_1 is not in a state capable of actually processing a substrate (not in an operable state). In the case of the example in FIG. 6, in the target section surrounded by the dotted line 420, the time length during which the substrate processing apparatus 120_1 may actually process the substrate (the time length during which the substrate may be operated) becomes “Tn.”

Here, the reference numeral 610 in FIG. 6 indicates a schedule of the substrate processing apparatus 120_1 at each time of the accumulated data 130. As seen from the comparison with the reference numeral 610, the time length during which the substrate processing apparatus 120_1 actually processes the substrate based on the recipe (the time length during operation) also depends on the schedule of the substrate processing apparatus 120_1.

That is, not only the time during which the substrate is not being processed due to the cause on the substrate processing apparatus 120_1 side such as maintenance on the substrate processing apparatus 120_1 or the occurrence of an abnormality during operation, but also the time during which the substrate is not being processed due to the schedule such as waiting or planned suspension is included.

Meanwhile, when calculating the operation rate of the substrate processing apparatus 120_1, it is appropriate to include, in the operating time, the time during which the substrate may be actually processed among the time during which the substrate is not processed. This is because the operator may appropriately grasp the past state of the substrate processing apparatus 120_1 by calculating the operation rate in this way.

In FIG. 6, the “calculation method of the operation rate of the comparative example” represents a state in which the operation rate of the target section surrounded by the dotted line 420 is calculated, based on the data content associated with “recipe executing/recipe not executing” of the accumulated data 130. According to the method of calculating the operation rate of the comparative example, the operation rate=Tᵣ/Tₜₒₜₐₗ. Further, “Tₜₒₜₐₗ” refers to the time that is included in the target section surrounded by the dotted line 420 in the time 620 after the substrate processing apparatus 120_1 is started up (Tₜₒₜₐₗ becomes equal to the target section except immediately after startup).

Meanwhile, in FIG. 6, the “calculation method of the operation rate of this example” represents a state in which the operation rate of the target section surrounded by the dotted line 420 is calculated, based on the data content associated with the “normal mode/maintenance mode” of the accumulated data 130. According to the method of calculating the operation rate of this example, the operation rate=Tₙ/Tₜₒₜₐₗ.

As described above, in the first embodiment, the operation rate is calculated using the data content corresponding to the data item that does not depend on the schedule of the substrate processing apparatus 120_1. Thus, according to the first embodiment, the operator may grasp the past state of the substrate processing apparatus 120_1.

Further, the example of FIG. 6 indicates a case where the “normal mode/maintenance mode” is used as the data item that does not depend on the schedule of the substrate processing apparatus 120_1.

However, data items other than the “normal mode/maintenance mode” may be used in the calculation of the operation rate in this example. Examples of data items other than the “normal mode/maintenance mode” include “online/offline” (not illustrated in FIG. 6).

Further, in the accumulated data 130, “online/offline” is associated with the data content indicating whether the substrate processing apparatus 120_1 is connected to the host apparatus 110. The case of online indicates that the substrate processing apparatus 120_1 is connected to the host apparatus 110 (i.e., in a state capable of actually processing the substrate). Meanwhile, the case of offline indicates that the substrate processing apparatus 120_1 is not connected to the host apparatus 110 (i.e., not in a state capable of actually processing the substrate).

<Flow of Operation Rate Calculation Process>

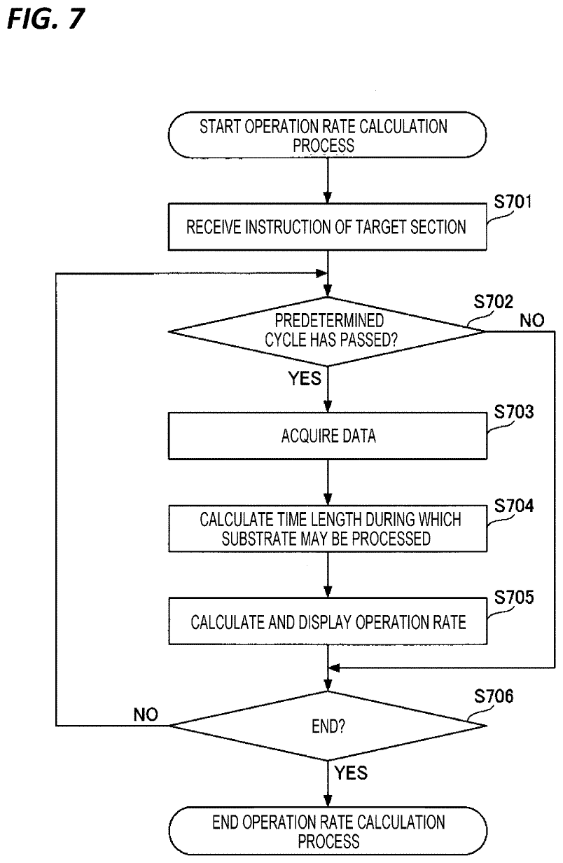

Next, descriptions will be made on a flow of the operation rate calculation process by the analysis apparatus 140. FIG. 7 is a flowchart illustrating a flow of the operation rate calculation process by the analysis apparatus. Further, during execution of the operation rate calculation process, the data acquisition unit 301 continuously acquires the accumulated data 130 from the substrate processing apparatus 120_1 and stores the accumulated data 130 in the data storage 310.

In step S701, the display controller 304 notifies the operation rate calculator 303 of the target section received on the customization screen 400.

In step S702, the display controller 304 determines whether a predetermined cycle has passed. When it is determined in step S702 that the predetermined cycle has not passed (in the case of “No” in step S702), the process proceeds to step S706.

When it is determined in step S702 that the predetermined cycle has passed (in the case of “Yes” in step S702), the process proceeds to step S703. In step S703, the display controller 304 instructs the operation rate calculator 303 to calculate an operation rate. In addition, the operation rate calculator 303 reads, from the data storage 310, the data content of the target section notified by the display controller 304 as the data content corresponding to the data item indicating whether the substrate may be processed.

In step S704, the operation rate calculator 303 calculates the time length during which the substrate may be processed based on the read data content.

In step S705, the operation rate calculator 303 calculates, as the operation rate, the ratio of the time length during which the substrate may be processed in the target section. Further, the display controller 304 displays the operation rate calculated by the operation rate calculator 303 on the management screen and displays the operation rates calculated in the past on the management screen.

In step S706, the display controller 304 determines whether to end the operation rate calculation process. When it is determined in step S706 that the operation rate calculation process is to be continued (in the case of “No” in step S706), the process returns to step S702. When it is determined in step S706 that the operation rate calculation process is to be ended (in the case of “Yes” in step S706), the operation rate calculation process is ended.

In this way, the analysis apparatus 140 calculates the operation rate as an index indicating the past state of the substrate processing apparatus 120_1 at predetermined intervals. Thus, the operator may monitor the operation rate and, when the operation rate is lowered (before the abnormality is detected), may take measures according to the cause of the drop. This allows the operator to prevent the occurrence of an abnormality in the substrate processing apparatus 120_1.

<Display Examples of Management Screen and Detailed Screen>

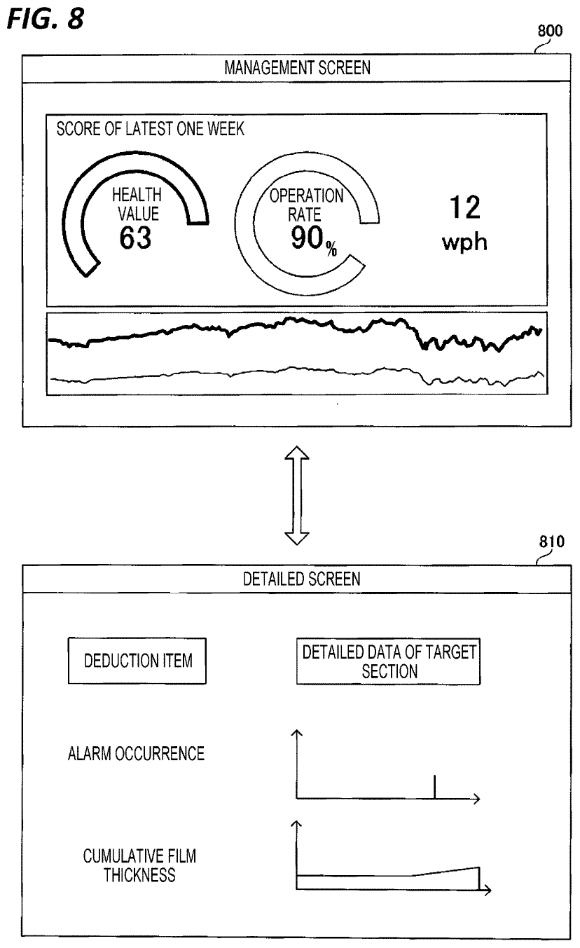

Next, descriptions will be made on display examples of the management screen and the detailed screen displayed on the display 205 of the analysis apparatus 140 by the display controller 304. FIG. 8 is a diagram illustrating examples of a management screen and a detailed screen displayed on the analysis apparatus.

As illustrated in FIG. 8, the health value and the operation rate calculated for the target section=“latest one week” are displayed in parallel on the management screen 800. Further, the management screen 800 displays past health value transitions and past operation rate transitions.

Thus, the operator may grasp the present and past states of the substrate processing apparatus 120_1 and their transitions at a glance.

Further, as illustrated in FIG. 8, when the operator specifies the “health value” on the management screen 800, the detailed screen 810 is displayed on the display 205 of the analysis apparatus 140. The detailed screen 810 displays the data item for which the deduction value has been calculated among the data items used for calculating the health value, and displays the corresponding data content (i.e., the data content of the target section). The example of the detailed screen 810 of FIG. 8 indicates a case where the deduction value calculated based on the data content corresponding to “alarm occurrence” and the data content corresponding to “cumulative film thickness” is “37” (=100-63).

In this way, by configuring so that the data content which causes the decrease in the health value may be referred to, the operator may refer to the data content when the health value decreases and determine whether to take a measure (or what type of measure is to be taken).

### SUMMARY

As is clear from the above description, the state management system according to the first embodiment reads the data contents of the specified target section as the data contents corresponding to a plurality of types of data items selected from the accumulated data accumulated in the substrate processing apparatus; calculates the deduction value for each data item by multiplying the read data contents by the specified weighting coefficient, and calculates the “health value,” which is one index indicating the current state of the substrate processing apparatus, by subtracting the value from the full score value; and displays the calculated health value on the management screen.

In this way, by calculating and displaying the health value from the accumulated data, the operator may easily grasp the current state of the substrate processing apparatus. In addition, when the health value is lowered (before the abnormality is detected), the operator may take measures according to the cause of the drop. This allows the operator to prevent the occurrence of an abnormality in the substrate processing apparatus 120_1.

In addition, the state management system according to the first embodiment reads the data contents of the specified target section from the accumulated data accumulated in the substrate processing apparatus as the data contents corresponding to the data items indicating whether the substrate may be processed; calculates the “operation rate,” which is one index indicating the past state of the substrate processing apparatus, based on the read data contents; and displays the calculated operation rate on the management screen.

In this way, by calculating and displaying the operation rate from the accumulated data, the operator may easily grasp the past state of the substrate processing apparatus. Further, when the health value is lowered (before the abnormality is detected), the operator may take measures according to the cause of the drop. This allows the operator to prevent the occurrence of an abnormality in the substrate processing apparatus.

As a result, according to the first embodiment, it is possible to provide a state management system and a state management method that make it easy to grasp the state of the substrate processing apparatus.

### Second Embodiment

In the first embodiment, descriptions have been made on the case where the health value and the operation rate are calculated by connecting the analysis apparatus 140 to the substrate processing apparatus 120_1 and acquiring the accumulated data accumulated in the substrate processing apparatus 120_1. However, a connection destination of the analysis apparatus 140 is not limited to the substrate processing apparatus 120_1 and may be simultaneously connected to a plurality of substrate processing apparatuses. Thus, it becomes possible to compare the states of the plurality of substrate processing apparatuses using a common index. Hereinafter, the second embodiment will be described focusing on the differences from the first embodiment.

<Display Example of Management Screen of Each Substrate Processing Apparatus>

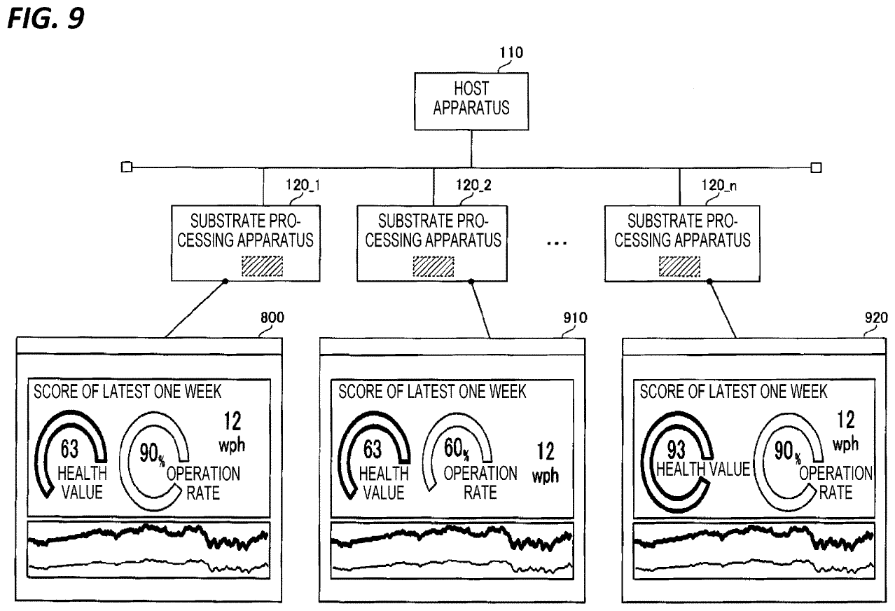

First, descriptions will be made on a display example in which a health value and an operation rate are calculated for each substrate processing apparatus based on the accumulated data of each of the substrate processing apparatuses 120_1 to 120_n and displayed on the management screen. FIG. 9 is a diagram illustrating a specific example of health values and operation rates calculated for a plurality of substrate processing apparatuses.

In FIG. 9, the management screen 800 represents a state in which the health value and the operation rate calculated based on the accumulated data accumulated in the substrate processing apparatus 120_1 are displayed in parallel. Similarly, the management screen 910 represents a state in which the health value and the operation rate calculated based on the accumulated data accumulated in the substrate processing apparatus 120_2 are displayed in parallel. Similarly, the management screen 920 represents a state in which the health value and the operation rate calculated based on the accumulated data accumulated in the substrate processing apparatus 120_2 are displayed in parallel.

Further, it is assumed that the health values displayed on any of the management screens 910 are calculated based on the same data item, the same weighting coefficient, and the same target section. It is also assumed that the operation rates displayed on any of the management screens 910 are calculated based on the same data item and the same target section.

In this way, according to the analysis apparatus 140, by displaying the current and past states of the plurality of substrate processing apparatuses using the common index, the operator may grasp the present and past states of the plurality of substrate processing apparatuses at a glance.

Also, by displaying the health value and the operation rate in parallel for each of the plurality of substrate processing apparatus, the substrate processing apparatus to be treated early may be properly determined based on a combination of high and low health values, high and low operation rates.

### SUMMARY

As is clear from the above description, the state management system according to the second embodiment acquires the accumulated data of a plurality of substrate processing apparatuses, calculates a health value based on the same data item, the same weighting coefficient, and the same target section, and also calculates an operation rate based on the same data item and the same target section, and displays, in parallel, the health value and the operation rate calculated based on the accumulated data of the plurality of substrate processing apparatuses.

Thus, the operator may grasp the current and past states of the plurality of substrate processing apparatuses at a glance. Further, the operator may appropriately determine the substrate processing apparatus to be treated at an early stage.

### Other Embodiments

In the first and second embodiments, the analysis apparatus 140 has been described as an apparatus that calculates and displays both a health value and an operation rate as an index indicating the current and past states of the substrate processing apparatus. However, the analysis apparatus 140 may be configured to calculate and display only one of the values.

Further, in the first and second embodiments described above, the substrate processing apparatus and the analysis apparatus are separately configured, but the substrate processing apparatus and the analyzing apparatus may be integrally configured.

In addition, in the first and second embodiments described above, the analysis apparatus has been described as having a data acquisition unit, a health value calculator, an operation rate calculator, and a display controller, but the substrate processing apparatus may have a part of the functions of each unit of the analysis apparatus.

Further, in the first and second embodiments, descriptions have been made on the case where the processing apparatus is the substrate processing apparatus. However, the processing apparatus that calculates the health value and the operation rate is not limited to the substrate processing apparatus and may be a processing apparatus other than the substrate processing apparatus.

According to the present disclosure, it is possible to provide a state management system and a state management method that make it easy to grasp the state of an apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A state management system comprising:
a memory; and
a processor coupled to the memory and configured to:
acquire data accumulated in an apparatus;
execute a process of combining a plurality of types of data selected in advance among acquired data, and calculating one index indicating a normality of the apparatus, at predetermined intervals; and
display the one index that has been calculated in a display.

2. A state management system comprising:
a memory; and
a processor coupled to the memory and configured to:
acquire data accumulated in an apparatus;
execute a process of extracting data indicating whether the apparatus is in an operable state from acquired data, and calculate one index indicating a ratio at which the apparatus is in the operable state, at predetermined intervals; and
display the one index that has been calculated in a display.

3. The state management system according to claim 1, wherein the processor executes the process on data of a target section specified in advance among the acquired data.

4. The state management system according to claim 2, wherein the processor executes the process on data of a target section specified in advance among the acquired data.

5. The state management system according to claim 1, wherein the processor calculates a deduction value by multiplying a weighting coefficient specified in advance with a plurality of types of data selected in advance, and calculates the one index by subtracting the deduction value from a full point value.

6. A state management system comprising:
a memory; and
a processor coupled to the memory and configured to:
acquire data accumulated in an apparatus;
execute a first process of combining a plurality of types of data selected in advance among acquired data, and calculate a first index indicating a normality of the apparatus, at predetermined intervals;
execute a second process of extracting data indicating whether the apparatus is in an operable state from the acquired data, and calculate a second index indicating a ratio at which the apparatus is in the operable state, at the predetermined intervals; and
display the first index and the second index in parallel in a display.

7. The state management system according to claim 6, wherein when the processor acquires data accumulated in a plurality of devices and calculates the first index for each of the plurality of devices, the processor calculates the first index by combining a plurality of types of common data selected in advance.

8. The state management system according to claim 7, wherein the processor calculates a deduction value by multiplying a common weighting coefficient specified in advance with the plurality of types of common data selected in advance, and calculates the first index by subtracting the deduction value from a full point value.

9. A state management method comprising:
acquiring data accumulated in an apparatus;
executing a process of combining a plurality of types of data selected in advance among the data acquired in the acquiring, and calculating one index indicating a normality of the apparatus, at predetermined intervals; and
displaying the one index calculated in the calculating in a display.

10. A state management method comprising:
acquiring data accumulated in an apparatus;
executing a process of extracting data indicating whether the apparatus is in an operable state from the data acquired in the acquiring, and calculating one index indicating a ratio at which the apparatus is in the operable state, at predetermined intervals; and
displaying the one index calculated in the calculating.

11. A state management method comprising:
acquiring data accumulated in an apparatus;
executing a first process of combining a plurality of types of data selected in advance among the data acquired in the acquiring, and calculating a first index indicating a normality of the apparatus, at predetermined intervals;
executing a second process of extracting data indicating whether the apparatus is in an operable state from the data acquired in the acquiring, and calculating a second index indicating a ratio at which the apparatus is in the operable state, at the predetermined intervals; and
displaying the first index and the second index in parallel in a display.
